(19) United States
(12) Patent Application Publication
(10) Pub. No.: US 2026/0100328 A1
(43) Pub. Date: Apr. 9, 2026

(54) AUTOMATED CHEMICAL SWITCHING FOR MATERIAL DELAYERING

(71) Applicant: FEI COMPANY, Hillsboro, OR (US)

(72) Inventors: Jeffrey Kmiec, Aloha, OR (US); Arun Sundar Sundaram Singaravelu, Portland, OR (US)

(21) Appl. No.: 18/906,788

(22) Filed: Oct. 4, 2024

(51) Int. Cl. H01J 37/30; H01J 37/28; H01J 37/305

(52) U.S. Cl. CPC H01J 37/3002; H01J 37/28; H01J 37/3053; H01J 2237/006; H01J 2237/221; H01J 2237/2814; H01J 2237/31749

(57) ABSTRACT

Provided herein is a method for delayering heterogeneous materials. Also provided herein is a method comprising delayering, at a first time, a multilayered material until a first endpoint condition is satisfied, determining a change to the delayering setting based on the first endpoint condition being satisfied, and delayering, at a second time subsequent to the first time, the multilayered material until a second endpoint condition is satisfied. Further provided herein is a non-transitory computer-readable medium embodying program code comprising instructions which, when executed by a processor, cause the processor to perform operations comprising delayering, at a first time, a multilayered material until a first endpoint condition is satisfied, determining a change to the delayering setting based on the first endpoint condition being satisfied, and delayering, at a second time subsequent to the first time, the multilayered material until a second endpoint condition is satisfied.

### BACKGROUND

The continued trend in tech of shrinking material features in, for example, semi-conductors, means that failure analysis is more challenging than ever before. Additionally, more advanced designs and complex 3D architectures result in an increasing number of non-homogenous layers, and increased complexity and sensitivity in materials.

Due to the reduction in feature dimensions and increase in structural complexity, device delayering is becoming more and more important for detecting device faults (as well as other phenomena that contribute to device failure). While damage-free deprocessing of single layers is critical, it can also be increasingly time consuming for various industrial and research and development applications. Therefore, development of automated and damage-free delayering of non-homogenous materials is of increasing interest. Automatic de-processing allows access to buried information for advanced devices that would otherwise be unattainable.

As a non-limiting example, heat assisted magnetic recording (HAMR) is a technique used to increase data storage density on spinning disc media. In the HAMR process, magnetic media is heated with a laser above the curie point to be magnetized by a write pole to record data. Applying heat allows a smaller cross-sectional area of the recording media to be used for increased storage densities. Laser light can be focused to a spot size of one quarter wavelength of the laser using a planar solid immersion wave guide mirror and near-field transducer (NFT). Light focused onto the wave guide is directed to the NFT. The NFT is composed of a circular disk and peg. The disc functions as an antenna and the peg confines the transfer of heat from the laser to a small spot on the magnetic disk media. An optimization process is done to find the correct NFT size and proper position on the wave guide.

When it comes to NFT refinement from a heterogeneous material or a multilayered material the challenges outlined above persist. There is, for example, uncertainty as to how much delayering processing time is needed to expose an NFT embedded in a heterogeneous material or a multilayered material which limits the possibilities of automation of the delayering process and thus, in proper device failure analysis. The present disclosure aims to solve this limitation and introduces a chemical gradient and method for automation of delayering in a wide range of materials.

### BRIEF SUMMARY

Provided herein is a method for delayering a heterogeneous material, the method comprising processing the heterogeneous material at a first time by at least: (i) directing a charged particle beam toward the heterogeneous material; (ii) directing a first gas composition toward the heterogenous material; generating a first set of images of the heterogeneous material; and (iii) detecting a first endpoint using the first set of images.

Further, the method for delayering a heterogeneous material comprises processing the heterogeneous material at a second time based on the first endpoint being detected, wherein the processing at the second time comprises: (v.) directing the charged particle beam toward the heterogeneous material; (vi.) directing a second gas composition toward the heterogenous material; (vii.) generating a second set of images of the heterogeneous material; and (viii.) detecting a second endpoint using the second set of images.

Also provided herein is a method comprising delayering, at a first time, a multilayered material until a first endpoint condition is satisfied, the delayering at the first time using at least a charged particle source and a gas source according to a first delayering setting, the first delayering setting controlling an energy of a charged particle beam emitted by the charged particle source and/or a first gas composition released by the gas source; determining a change to the delayering setting based on the first endpoint condition being satisfied, the change being to at least the first gas composition and resulting in a second delayering setting; and delayering, at a second time subsequent to the first time, the multilayered material until a second endpoint condition is satisfied, the delayering at the second time using at least the charged particle source and/or a second gas source according to the second delayering setting.

Further provided herein is a non-transitory computer-readable medium embodying program code comprising instructions which, when executed by a processor, cause the processor to perform operations comprising delayering, at a first time, a multilayered material until a first endpoint condition is satisfied, the delayering at the first time using at least a charged particle source and a gas source according to a first delayering setting, the first delayering setting controlling an energy of a charged particle beam emitted by the charged particle source or a gas composition released by the gas source; determining a change to the delayering setting based on the first endpoint condition being satisfied, the change being to at least the gas composition and resulting in a second delayering setting; and delayering, at a second time subsequent to the first time, the multilayered material until a second endpoint condition is satisfied, the delayering at the second time using at least the charged particle source and the gas source according to the second delayering setting.

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1 is a schematic diagram of an example dual beam system, according to some embodiments of the present disclosure.

FIG. 2 is a schematic diagram showing the gas source in a dual beam system and its relevant components, according to some embodiments of the present disclosure.

FIG. 3 is a flowchart for delayering a multilayered material, according to embodiments of the present disclosure.

FIG. 4 shows a scanning electron microscopy (SEM) image highlighting the focused ion beam (FIB) region, according to embodiments of the present disclosure.

FIGS. 5A-5D show a series of SEM images of the grayscale increase through the first stage of the delayering process, according to embodiments of the present disclosure. FIG. 5A shows the grayscale SEM image of a non-homogenous surface at time zero. FIG. 5B shows the grayscale SEM image after 1.12358 minutes of delayering. FIG. 5C shows the grayscale SEM image after 1 second of delayering. FIG. 5D shows the grayscale SEM image after 400 milliseconds of delayering.

FIG. 6 shows a plot of the current over initial grayscale per delayering time (in minutes) with a dashed line showing the 30% increase threshold marking the end of stage one, according to embodiments of the present disclosure.

FIG. 7 shows and SEM image of the FIB pattern rectangle region following stage one of the delayering process, according to embodiments of the present disclosure.

FIGS. 8A-8C show a series of SEM images of the paddle for measuring the paddle slope in stage two of the delayering process, according to embodiments of the present disclosure. FIG. 8A shows an SEM image taken right after the end of stage one, at a time of 0 seconds of stage two. FIG. 8B shows the SEM image taken after three seconds of the second stage delayering process. FIG. 8C shows the SEM image taken after six seconds of the second stage delayering process.

FIG. 9 shows a plot of the slope of the best fit line measured at each of the different timepoints of exposure for stage two of the delayering process with a dashed line showing the threshold marking the end of stage two, according to embodiments of the present disclosure.

FIG. 10 shows a plot of the coefficient of determination (R²) determined by fitting the slope data obtained of the different timepoints of exposure for stage two of the delayering process with a dashed line showing the threshold marking the end of stage two, according to embodiments of the present disclosure.

FIG. 11 shows SEM images of the first endpoint and the second endpoint of the delayering process, respectively, according to embodiments of the present disclosure.

FIG. 12 shows a block diagram of an example computer system usable with systems and methods, according to embodiments of the present disclosure.

### DETAILED DESCRIPTION

Before the present disclosure is described in detail, it is to be understood that the terminology used herein is for purposes of describing particular examples and embodiments only and is not intended to be limiting.

In this detailed description and in the claims that follow, reference will be made to a number of terms that shall be defined to have the following meanings:

As used herein, the terms “optional” or “optionally” mean that the subsequently described feature or structure may or may not be present, or that the subsequently described event or circumstance may or may not occur, and that the description includes instances where a particular feature or structure is present and instances where the feature or structure is absent, or instances where the event or circumstance occurs and instances where it does not.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. Any recitation herein of the term “comprising”, particularly in a description of components of a composition, in a description of a method, or in a description of elements of a device, is understood to encompass those compositions, methods, or devices consisting essentially of and consisting of the recited components or elements, optionally in addition to other components or elements. The invention illustratively described herein suitably may be practiced in the absence of any element, elements, limitation, or limitations which is not specifically disclosed herein.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed within the invention. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included in the invention.

The terms “about” or “approximate” and the like are synonymous and are used to indicate that the value modified by the term has an understood range associated with it, where the range can be ±20%, ±15%, ±10%, ±5%, or ±1%. The terms “substantially” and the like are used to indicate that a value is close to a targeted value, where close can mean, for example, the value is within 80% of the targeted value, within 85% of the targeted value, within 90% of the targeted value, within 95% of the targeted value, or within 99% of the targeted value.

The present disclosure relates to material delayering. In certain embodiments, the present disclosure relates to automating the process of material delayering by, for example, switching a method for delayering a material. In certain embodiments the delayering can be done by chemical means. In certain embodiments, the present disclosure relates to automating the process of material delayering by, for example switching the chemistry needed to delayer a surface. In certain embodiments, the present disclosure relates to delayering a material and controlling the delayering based on how much of the material has been removed and/or how much of the material is yet to be removed. The dependencies can be defined as endpoint conditions. In certain embodiments, a delayering system starts using a first set of controls (e.g., a first gas composition). Once a first endpoint condition is satisfied, the delayering system switches to using a second set of controls (e.g., a second gas composition). The delayering continues until a final endpoint condition is satisfied.

A gas composition is one example of controls usable in delayering a material. Other examples of controls exist and can include any or a combination of: intensity of a charged particle beam, the measurements of a pre-defined parameter, temperature of the material, the time of exposure to the charged particle beam and/or a delayering gas composition. Other embodiments and conditions are discussed in the following detailed description and non-limiting examples.

As one non-limiting illustrative use case, the present disclosure relates to automating the process of switching the chemistry needed to expose a near-field transducer (NFT), buried within a heterogeneous material or multilayered material, through a delayering process. The NFT device may be located below the surface of, for example, a wafer. The wafer structures above the NFT must be removed before the NFT can be exposed to the surface for imaging. Wafer structures above the NFT may be delayered using a charged particle beam, for example, a focused ion beam (FIB). In one non-limiting use case, the FIB is a plasma FIB (pFIB) or a dual beam FIB (DB FIB). Other examples of a charged particle beam may include, but are not limited to, an electron beam induced etching (EBIE), focused electron beam induced etching (FEBIE), etc. In certain embodiments, the wafer is tilted normal to the FIB column. FIB delayering is a physical removal process which can be chemically enhanced by delivering gas composition to the delayering site using a multi chemical gas injection system wherein the gas envelops the entire chamber where the wafer is being processed. The FIB column allows delayering to occur due to the physical bombardment of plasma on the wafer surface. The gas injection system allows delayering to occur due to chemical reactions on the wafer surface to a more refined degree. The progress of delayering may be monitored using charged particle microscope images, for example scanning electron microscope (SEM) images, by tilting the sample stage normal to the SEM column. Other charged particle microscopes may also include a transmission electron microscope (TEM), a field emission scanning electron microscope (FESEM), a reflection electron microscope (REM), a scanning tunneling microscope (STM), etc. In embodiments of the present disclosure, where a dual beam system is used, the dual beam does not need operator input to switch the delayering gas chemistry which makes the process fully automated.

In certain embodiments, the present disclosure related to delayering a heterogeneous material. A heterogeneous material may comprise an irregular deposition of NiFe (Yoke) and aluminum(II) oxide (AlO) material above the NFT device. Other heterogeneous materials may relate to the irregular deposition of silicon dioxide (SiO₂), silicon nitride (Si₃N₄), or polysilicon (poly-Si). However, in one non-limiting specific use case, methods that may be used to automatically switch the delayering chemistry to delayer NiFe and AlO material above the NFT device are outlined.

Not intending to be bound by theory, in one non-limiting use case, the processing time for delayering a heterogeneous surface may be uncertain due to the variation in AlO and NiFe thickness across the surface of the heterogeneous material. Another possibility for uncertainty in the delayering process time is variation in delayering rate of material removal over time. Regardless of what causes delayering process time uncertainty, the processing metrics may not change. In one, non-limiting example, the processing metrics may involve analysis of the charged particle microscope output. In certain embodiments, the output may be analyzed by grayscale analysis. In certain embodiments, the output may be analyzed by slope and edge formation analysis. In certain embodiments, the output may be analyzed by light intensity. In certain embodiments, the output may be analyzed using a combination of the non-limiting metrics. In one, non-limiting example, analyzing the grayscale changes in the device in combination with formation of edges with particular characteristics, may be used to determine when a delayering process is completed at each site. In addition to determining when delayering process is completed and when the gas chemistry should be changed, the total time needed for each process provides a starting point for how long the next site should be deprocessed. Knowing how long it takes to delayer each site with each gas chemistry improves the process throughout as well because time is saved by analyzing the process completeness close in time to when the process is nearing completion and not towards the beginning of the process when the device is statistically not likely to be near completion.

According to the present disclosure, the delayering chemistry encompasses the use of at least Ammonium Carbide (AC) gas and Delineation Etch (DE) gas. AC gas has high selectivity for delayering the NiFe material and low selectivity for delayering the AlO. In contrast, DE gas has high selectivity for delayering, for example, AlO, and low selectivity for delayering NiFe. Not intending to be bound by theory, these differences in delayering selectivity render a combination of AC and DE gas a preferrable combination to perform the delayering process. Accordingly, etch rate may vary for different materials because the strength of the etch reaction may vary with different materials, the sticking coefficient of the gas may be different for different materials, and the reaction products may be different having different degrees of volatility. Not intending to be bound by theory, an AC gas or a DE gas may inhibit the etching of some materials by producing a reaction product that is not volatile and that forms a protective film over the second layer.

In some embodiments, molecules of a DE gas compound are adsorbed onto the surface of a specimen in a charged particle system. As noted above, the gas causes different materials on the specimen to be etched at different rates in the presence of a charged particle beam. Such selective etching provides a sharp, clean cross section that allows the various layers in the cross section to be readily distinguishable. Selective etching also allows the removal of some materials without significantly affecting other materials on a sample. A molecule of the DE gas compound preferably includes an etching portion and a functional group to increase the stickiness of the molecule and enhance adsorption. Not intending to be bound by theory, it is believed that the gas is adsorbed onto the surface of the exposed layers and the charged particle bombardment provides energy to initiate a reaction of the adsorbed gas molecule with the surface material to be etched. The reaction produces volatile products that dissipate in the vacuum chamber, thereby removing material from or etching the specimen.

In some embodiments, a DE gas compound comprises a halogenated hydrocarbon with an added functional group to enhance adsorption. For example, 2,2,2-trifluoroacetamide (CF₃CONH₂) or xenon difluoride (XeF₂) may selectively etch ILD layers or silicon layers, respectively, so that they can be distinguished using SEM or FIB imaging. In some embodiments, a DE gas compound may be preferably characterized by a sticking coefficient that is sufficiently high to ensure that molecules will adhere to the substrate surface in sufficient concentrations to react with the surface molecules in the presence of an ion beam. Not intending to be bound by theory, an etchant can be functionalized as an approach to modifying its sticking coefficient. For example, CF₃CONH₂ includes the functional amido group that is believed to enhance the stickiness of the compound. In some embodiments, the CF₃ portion of the molecule or the fluorine that is liberated in the reaction with the ion beam is believed to be responsible for the etching. In some embodiments, the DE gas compound may be preferably selected based on its etching features as related to the substrate surface. Other DE gas compounds include, but are not limited to, trifluoroacetic acid (CF₃COOH), pentafluoropropionic acid (CF₃CF₂COOH), trifluoroacetyl fluoride (CF₃COF), 3,3,3-trifluorolactic acid (CF₃COHCOOH), and hexafluoroacetone (CF₃C[O]CF₃).

In order to determine when the AC and DE gas chemistry should be switched, grayscale and edge finders were used to determine preferred endpoints in a two-stage process. By automating the process of switching AC and DE gas, the present disclosure improves the repeatability of achieving a proper delayering result, reducing the need for manual input from a charged particle system operator. The present disclosure further provides a way to increase the throughput of delayering a, for example, heterogeneous surface because the process of monitoring the extent of delayering with charged particle microscope images, e.g., SEM images, can be reduced to points in time of the process where the delayering gas chemistry nearly needs to be changed.

As discussed above, the present disclosure provides a way to convert a semi-automated delayering process into a fully automated delayering process. In the fully automated process, the extent of the processing features may be determined mathematically by establishing endpoint criteria and without relying on individual review. Once endpoint criteria are established, the delayering process can be allowed to continue automatically until the endpoint criteria has been reached at each delayering site.

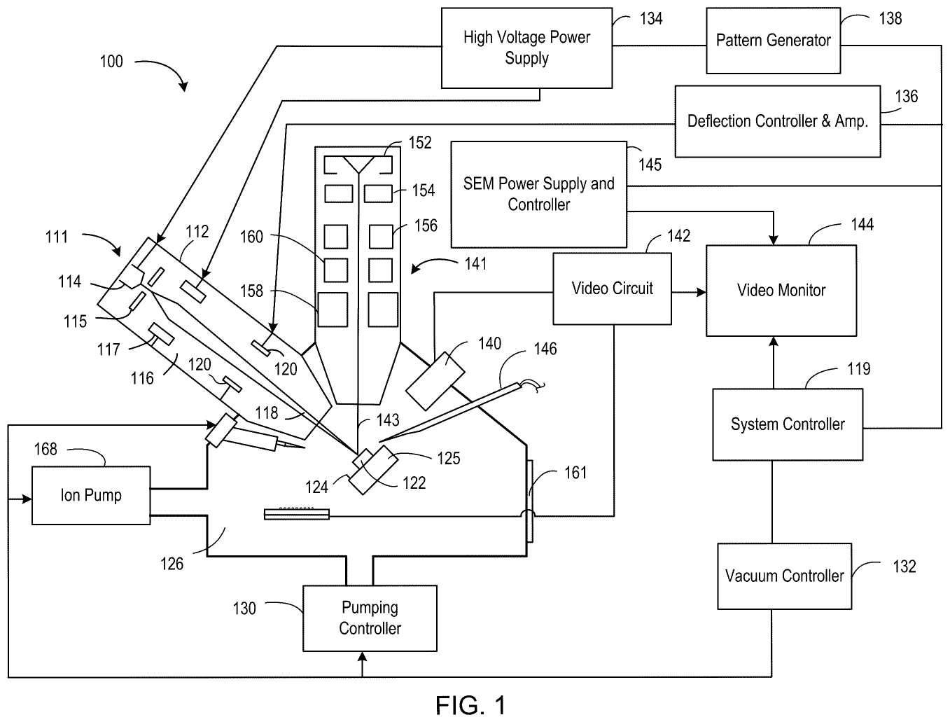

FIG. 1 is a schematic diagram of an example dual beam system 100, according to some embodiments of the present disclosure. System 100 may be used to implement material delayering discussed herein. In some embodiments, system 100 will perform sample delayering. However, in other embodiments, the delayering algorithms may be performed by a computing system coupled to system 100, such as at a user's desk or a cloud-based computing system. While an example of suitable hardware is provided below, the present disclosure is not limited to being implemented in any particular type of hardware. Various embodiments of delayering methods as described herein may be implemented using one or more algorithms performed by the computing system coupled to system 100.

In one non-limiting example, SEM 141, along with power supply and control unit 145, are provided with the dual beam system 100. An electron beam 143 is emitted from a cathode 152 by applying voltage between cathode 152 and an anode 154. Electron beam 143 is focused to a fine spot by means of a condensing lens 156 and an objective lens 158. Electron beam 143 is scanned two-dimensionally on the specimen by means of a deflector 160. Operation of condensing lens 156, objective lens 158, and deflector 160 is controlled by power supply and control unit 145.

Electron beam 143 can be focused onto sample 122, which is on stage 125 within exposure chamber 126 (as used herein, “exposure chamber” is used synonymously with “enveloping chamber” as further described below). Sample 122 may be located on a surface of stage 125 or on sample holder 124, which extends from the surface of stage 125.

When the electrons in the electron beam strike sample 122, secondary electrons are emitted. These secondary electrons are detected by secondary electron detector 140.

System 100 also includes FIB system 111 which includes an evacuated chamber having an ion column 112 within which are located an ion source 114 and focusing components 116 including extractor electrodes and an electrostatic optical system. The axis of focusing column 116 may be tilted, fifty-two degrees for example, from the axis of the electron column 141. The ion column 112 includes an ion source 114, an extraction electrode 115, a focusing element 117, deflection elements 120, which operate in concert to form focused ion beam 118. Focused ion beam 118 passes from ion source 114 through focusing components 116 and between electrostatic deflection means schematically indicated at 120 toward substrate 122, which may include, for example, a semiconductor wafer positioned on movable stage 125 within exposure chamber 126. System 100 also includes a gas injection source 146.

Stage 125 can move in a horizontal plane (X and Y axes) and vertically (Z axis). Stage 125 can also tilt and rotate about the Z axis.

A door 161 is opened for inserting substrate 122 onto stage 125. Depending on the tilt of the stage 124/125, the Z axis will be in the direction of the optical axis of the relevant column. For example, during a data gathering stage of the disclosed techniques, the Z axis will be in the direction, e.g., parallel with, the FIB optical axis as indicated by the ion beam 118. In such a coordinate system, the X and Y axis will be referenced from the Z-axis. For example, the X-axis may be in and out of the page showing FIG. 1, whereas the Y-axis will be in the page, all while all three axes maintain their perpendicular nature to one another.

The exposure chamber 126 is evacuated with turbomolecular and mechanical pumping system 130 under the control of vacuum controller 132. The vacuum system provides within exposure chamber 126 a vacuum of between approximately 1×10⁻⁷ Torr and 5×10⁻⁴ Torr. If an etch assisting gas, an etch retarding gas, or a deposition precursor gas is used, the chamber background pressure may rise, typically to about 1×10⁻⁵ Torr.

The high voltage power supply provides an appropriate acceleration voltage to electrodes in focusing column 116 for energizing and focusing ion beam 118. When it strikes sample 122, material is sputtered, that is physically ejected, from the sample. Alternatively, ion beam 118 can decompose a precursor gas to deposit a material.

High voltage power supply 134 is connected to ion source 114 as well as to appropriate electrodes in ion beam focusing components 116 for forming an approximately 500 eV to 30 keV ion beam 118 and directing the same toward a sample. Deflection controller and amplifier 136, operated in accordance with a prescribed pattern provided by pattern generator 138, is coupled to deflection plates 120 whereby ion beam 118 may be controlled manually or automatically to trace out a corresponding pattern on the upper surface of substrate 122. In some systems the deflection plates are placed before the final lens, as is well known in the art. Beam blanking electrodes (not shown) within ion beam focusing column 116 cause ion beam 118 to impact onto blanking aperture (not shown) instead of sample 122 when a blanking controller (not shown) applies a blanking voltage to the blanking electrode.

The ion source 114 typically provides an ion beam based on the type of ion source. In some embodiments, the ion source 114 is a liquid metal ion source that can provide a gallium ion beam, for example. In other embodiments, the ion source 114 may be plasma-type ion source that can deliver a number of different ion species, such as oxygen, xenon, argon, nitrogen, etc. The ion source 114 typically is capable of being focused into a sub one-tenth micrometer wide beam at substrate 122 for either modifying the substrate 122 by ion milling, ion-induced etching, material deposition, or for the purpose of imaging the substrate 122.

A charged particle detector 140, such as an Everhart-Thornley detector or multi-channel plate, used for detecting secondary ion or electron emission is connected to a video circuit 142 that supplies drive signals to video monitor 144 and receiving deflection signals from a system controller 119. The location of charged particle detector 140 within lower chamber 126 can vary in different embodiments. For example, a charged particle detector 140 can be coaxial with the ion beam and include a hole for allowing the ion beam to pass. In other embodiments, secondary particles can be collected through a final lens and then diverted off axis for collection.

System controller 119 controls the operations of the various parts of dual beam system. Through system controller 119, a user can cause a charged particle beam 118 (e.g., an ion beam such as FIB) or electron beam 143 to be scanned in a desired manner through commands entered into a conventional user interface (not shown). Alternatively, system controller 119 may control the dual beam system in accordance with programmed instructions stored in a memory. In some embodiments, the dual beam system incorporates image recognition software to automatically identify regions of interest, and then the system can manually or automatically extract samples in accordance with the present disclosure. For example, the system could automatically locate similar features on semiconductor wafers including multiple devices and take samples of those features on different (or the same) devices.

Layers of sample 122 can be removed from the working surface. Layers can be removed in smaller “slices” according to certain embodiments, in which slices of about 1 nm to 5 nm are removed sequentially. After the slice is removed, the newly exposed surface is imaged. The process of image acquisition and slice removal may be repeated for twenty-five, fifty, seventy-five, or one hundred times, but any other number of slices are contemplated herein. In terms of ranges, the process of image acquisition and slice removal may be repeated from at least one to twenty-five times, from at least twenty-five to fifty times, from at least fifty to seventy-five times, or from at least seventy-five to one hundred times.

The removal of a layer of material from the sample 122 can be done by directing the charged particle beam 118 (e.g., FIB) toward a portion of the sample 122 in a pattern and the injection of a gas from the gas injection source 146 into the exposure chamber 126. When a gas is applied to the exposure chamber 126 the exposure chamber 126 may be better referred to as the enveloping chamber 126 to describe the diffusion of the gas. For example, the ion beam may raster over the surface of the sample 122 in the portion, removing the desired layer and at the same time, the enveloping chamber 126 may be saturated with the gas composition of interest to assist with the delayering process for pre-defined periods of time. Embodiments of the present disclosure provide methods and systems for diverting an ion beam, introducing a gas composition, and removing the desired layer from the sample 122 using the diverted ion beam and the gas composition.

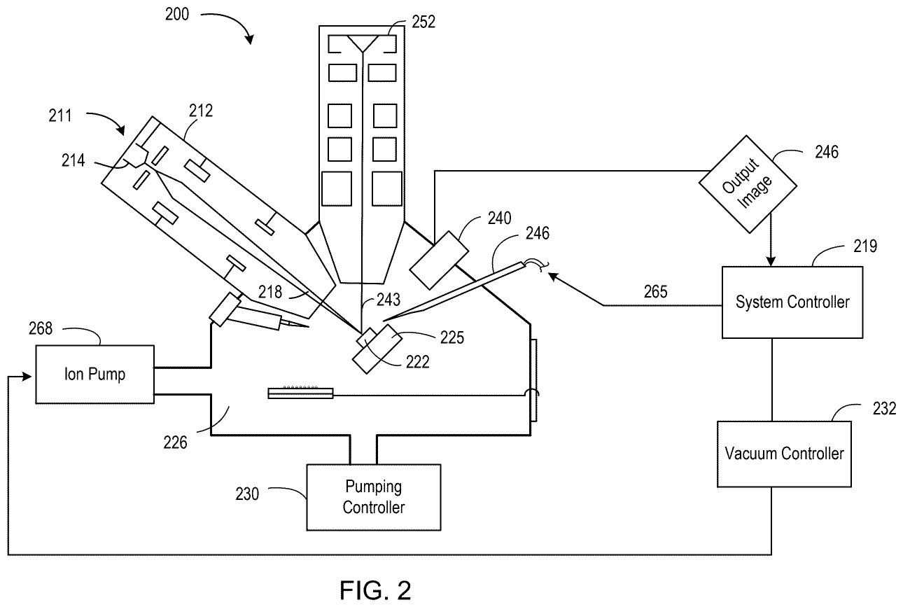

FIG. 2 shows a schematic diagram of a non-limiting example of the present disclosure 200 where particular components from the system 100 of FIG. 1 are shown and can be used as a delayering system. In certain embodiments, the present disclosure relates to delayering with a charged particle source 212 and one gas composition, imaging with SEM 252, detecting endpoint conditions, and controlling the gas composition introduced through the gas injection source 246 into the enveloping chamber 226, accordingly. An etch assisting gas, an etch retarding gas, or a deposition precursor gas may be introduced to the enveloping chamber 226 from the gas injection source 246. The gas may be injected locally from the gas injection source 246 to the enveloping chamber 162 at the same time that the charged particle beam 218 is applied to the sample 222. The charged particle beam 218 and the gas from the gas injection source 246 interact with the material that is exposed to the surface of the, for example, semiconductor wafer such that a layer of the material is removed. The electron beam 243 can be controlled (e.g., emitted once the charged particle beam 218 is no longer applied) such that the charged particle detector 240 can detect charged particles resulting from the interaction of the electron beam 243 with the delayered material. The charged particle detector 240 can output an image 248 based on the detected charged particles or measurements related to such particles such than the image can be generated (e.g., by the video circuit 142, FIG. 1). The system controller 219 can process the image (and similarly other images) to detect whether an endpoint condition is met and, dependently on the endpoint condition, cause switching a composition control 265 or maintaining the composition control 265 with the same gas introduced by the gas injection source 246 into the enveloping chamber 226 or stop the flow of gas into the enveloping chamber 226 altogether.

In certain embodiments, the disclosure relates to a method for delayering a heterogeneous material (e.g., 122 or 222), the method comprising processing the heterogeneous material at a first time by at least: (i.) directing a charged particle beam (e.g., 118 or 218) toward the heterogeneous material (e.g., 122 or 222); (ii.) directing a first gas composition toward the heterogenous material (e.g., where 146 or 246 represent the source of the first gas composition); (iii.) generating a first set of images of the heterogeneous material (e.g., 248); and (iv.) detecting a first endpoint using the first set of images.

In certain embodiments, the disclosure further relates to a method for processing the heterogeneous material at a second time based on the first endpoint being detected, wherein the processing at the second time comprises: (v.) directing the charged particle beam (e.g., 118 or 218) toward the heterogeneous material (e.g., 122 or 222); (vi.) directing a second gas composition toward the heterogenous material (e.g., where 146 or 246 represent the source of the second gas composition); (vii.) generating a second set of images of the heterogeneous material (e.g., 248); and (viii.) detecting a second endpoint using the second set of images.

In certain embodiments, the charged particle beam (e.g., 118 or 218) is a focused ion beam and wherein the energy of the focused ion beam is the same or different for delayering steps i. and v. In certain embodiments, the charged particle beam may refer to a plasma focused ion beam (PFIB), an electron beam induced etching (EBIE), a focused electron beam induced etching (FEBIE), and the like. In certain embodiments, a charged particle beam may be used in conjunction with a charged particle microscope. As used herein, a “charged particle microscope” may refer to a transmission electron microscope (TEM), scanning transmission electron microscope (STEM), dual beam systems including an ion beam source and an electron beam source, reflection electron microscopes (REM), circuit editing microscopes, or the like. Accordingly, the disclosure and claims are not to be considered limited to any particular example charged particle system discussed but can be utilized broadly with any number of electron microscopes that may exhibit some or all of the electrical or chemical characteristics of the discussed examples.

In certain embodiments, the first gas composition includes a mixture of at least two gases. In certain embodiments, the first gas composition and the second gas composition differ in the number of gases and/or in the constituent gases that make up each respective composition. In certain embodiments, the first gas composition comprises a mixture of ammonium carbide (AC) gas, delineated etch (DE) gas, gallium (Ga) gas, argon (Ar) gas, oxygen (O₂) gas, xenon (Xe) gas, chlorine (Cl₂) gas, fluorine-based gases (e.g., SF₆, CF₄), water vapor (H₂O), Iodine (I₂), or the like. In one illustrative example, the first gas composition may comprise a mixture of AC and DE gas.

In certain embodiments, the first gas composition comprises between about 0.0% and about 1.0% AC and between about 0.0% and about 80.0% DE. In certain embodiments, the first gas composition comprises 0.2% AC and 1.7% DE.

In terms of ranges, the first gas composition comprises between 0.0% and 0.1% AC, between 0.1% and 0.2% AC, between 0.2% and 0.3% AC, between 0.3% and 0.4% AC, between 0.4% and 0.5% AC, between 0.5% and 0.6% AC, between 0.6% and 0.7% AC, between 0.7% and 0.8% AC, between 0.8% and 0.9% 1.0% AC. In terms of ranges, the first gas comprises at least 0.0% to at least 0.2% AC, at least 0.1% to at least 0.3% AC, at least 0.2% to at least 0.4% AC, at least 0.3% to at least 0.5% AC, at least 0.4% to at least 0.6% AC, at least 0.5% to at least 0.7% AC, at least 0.6% to at least 0.8% AC, at least 0.7% to at least 0.9% AC, at least 0.8% to at least 1.0% AC. In certain embodiments, the first gas has at least 0.0% AC, at least 0.1% AC, at least 0.2% AC, at least 0.3% AC, at least 0.4% AC, at least 0.5% AC, at least 0.6% AC, at least 0.7% AC, at least 0.8% AC, at least 0.9% AC, or at least 1.0% AC.

In terms of ranges, the first gas composition comprises between about 0.0% and about 5.0% DE, between about 5.0% and about 10.0% DE, between about 10.0% and about 15.0% DE, between about 15.0% and about 20.0% DE, between about 20.0% and about 25.0% DE, between about 25.0% and about 30.0% DE, between about 30.0% and about 35.0% DE, between about 35.0% and about 40.0% DE, between about 40.0% and about 45.0% DE, between about 45.0% and about 50.0% DE, between about 50.0% and about 55.0% DE, between about 60.0% and about 65.0% DE, between about 65.0% and about 70.0% DE, between about 70.0% and about 75.0% DE, or between about 75.0% and about 80.0% DE. In terms of ranges, the first gas comprises at least 0.0% to at least 10.0% DE, at least 5.0% to at least 15.0% DE, at least 10.0% to at least 20.0% DE, at least 15.0% to at least 25.0% DE, at least 20.0% to at least 30.0% DE, at least 25.0% to at least 35.0% DE, at least 30.0% to at least 40.0% DE, at least 35.0% to at least 45.0% DE, at least 40.0% to at least 50.0% DE, at least 45.0% to at least 55.0% DE, at least 50.0% to at least 60.0% DE, at least 55.0% to at least 65.0% DE, at least 60.0% to at least 70.0% DE, at least 65.0% to at least 75.0% DE, or at least 70.0% to at least 80.0% DE. In certain embodiments, the first gas composition has at least 0.0% DE, at least 5.0% DE, at least 10.0% DE, at least 15.0% DE, at least 20.0% DE, at least 25.0% DE, at least 30.0% DE, at least 35.0% DE, at least 40.0% DE, at least 45.0% DE, at least 50.0% DE, at least 55.0% DE, at least 60.0% DE, at least 65.0% DE, at least 70.0% DE, at least 75.0% DE, or at least 80.0% DE.

In certain embodiments, the first set of images are charged particle microscope images wherein detecting the first endpoint comprises analyzing the charged particle images with a grayscale algorithm. In certain embodiments, the first set of images are charged particle microscope images, e.g., SEM images or TEM images, wherein detecting the first endpoint comprises analyzing the charged particle images, e.g., SEM images or TEM images, with a grayscale algorithm.

In certain embodiments, the first endpoint is detected by the grayscale algorithm, wherein a target grayscale increase in the first set of images is between 15% and 45%. As used herein, a grayscale measurement of 0% is defined by the first image collected, at time is zero seconds after 98% delayering of a heterogeneous or multilayered material has been achieved. At 98% delayering (i.e., time equal zero second) the features of the target structure are revealed but not yet defined. The time of zero seconds is defined prior to automation of the delayering system during the setup of the first processing stage. Increase in grayscale is therefore based on a 98% delayered baseline grayscale image. As used herein, delayering wherein there is over 50% increase in grayscale from the baseline may be destructive to the integrity of the target structure. As used herein, 100% increase in grayscale may refer to a fully delayered heterogeneous or multilayered material where the target structure has also been delayered/destroyed.

In terms of ranges, a target grayscale increase in the first set of images is between 15% and 20%, between 20% and 30%, between 25% and 35%, between 30% and 40%, or between 35% and 45%. In certain embodiments, the target grayscale is at least 15%, at least 16%, at least 17%, at least 18%, at least 19%, at least 20%, at least 21%, at least 22%, at least 23%, at least 24%, at least 25%, at least 26%, at least 27%, at least 28%, at least 29%, at least 30%, at least 31%, at least 32%, at least 33%, at least 34%, at least 35%, at least 36%, at least 37%, at least 38%, at least 39%, at least 40%, at least 41%, at least 42%, at least 43%, at least 44%, or at least 45%

In certain embodiments, the time it takes to arrive at the first endpoint is recorded to automate processing of the heterogeneous material at a first time.

In certain embodiments, the second gas composition comprises at least one gas. In certain embodiments, the second gas composition is selected from the group consisting of ammonium carbide (AC) gas, delineated etch (DE) gas, gallium (Ga) gas, argon (Ar) gas, oxygen (O₂) gas, xenon (Xe) gas, chlorine (Cl₂) gas, fluorine-based gases (e.g., SF₆, CF₄), water vapor (H₂O), Iodine (I₂), and the like. In one illustrative example, the second gas composition includes DE and excludes AC. In certain embodiments, the second set of images are charged particle microscope images. In certain embodiments, detecting the second endpoint comprises processing the charged particle images using an edge finding algorithm. In certain embodiments, the second set of images are charged particle microscope images, e.g., SEM or TEM images, which are used with an edge finding algorithm to detect the second endpoint.

In certain embodiments, the detecting the second endpoint comprises measuring a slope for each of the second set of images such that slope measurements are generated; and line fitting the slope measurements until an average of line fitted slope measurements is greater than 0.950 or wherein a coefficient of determination (R²) is greater than 0.996. In certain embodiments, the average slope of the fitted line is greater than 0.950, greater than 0.955, greater than 0.960, greater than 0.965, greater than 0.970, greater than 0.975, greater than 0.980, greater than 0.985, or greater than 0.990. In certain embodiments the coefficient of determination (R²) is greater than 0.996, greater than 0.997, or greater than 0.998.

In certain embodiments, the disclosure relates to a method comprising delayering, at a first time, a multilayered material until a first endpoint condition is satisfied, the delayering at the first time using at least a charged particle source (e.g., 112 or 212) and a gas source (e.g., 146 or 246) according to a first delayering setting, the first delayering setting controlling an energy of a charged particle beam (e.g., 118 or 218) emitted by the charged particle source (e.g., 112 or 212) and/or a first gas composition released by the gas source (e.g., 146 or 246). In certain embodiments, the disclosure relates to a method further comprising determining a change to the delayering setting based on the first endpoint condition being satisfied, the change being to at least the gas composition and resulting in a second delayering setting. In certain embodiments, the method also comprises delayering, at a second time subsequent to the first time, the multilayered material until a second endpoint condition is satisfied, the delayering at the second time using at least the charged particle source (e.g., 112 or 212) and the gas source (e.g., 146 or 246) according to the second delayering setting.

In certain embodiments, the multilayered material is a homogeneous multilayered material or a heterogeneous multilayered material. In certain embodiments, the multilayered material is made out of silicon (Si), silicon carbide (SiC), gallium arsenide (GaAs), gallium nitride (GaN), sapphire (Al₂O₃), gallium nitride (GaN), germanium (Ge), silicon-on-insulator (SOI), indium phosphide (InP), and the like, or a combination thereof.

In certain embodiments, delayering, at a first time, comprises: (i.) directing a focused ion beam (e.g., 118 or 218) toward the multilayered material (e.g., 122 or 222); (ii.) directing the first gas composition toward the multilayered material (e.g., where 146 or 246 represent the source of the first gas composition); (iii.) generating a first set of images of the multilayered material (e.g., 248); and (iv.) detecting the first endpoint using the first set of images.

In certain embodiments, delayering, at a second time subsequent to the first time, comprises: (v.) directing a focused ion beam (e.g., 118 or 218) toward the multilayered material (e.g., 122 or 222); (vi.) directing the second gas composition toward the multilayered material (e.g., where 146 or 246 represent the source of the second gas composition); (vii.) generating a second set of images of the multilayered material (e.g., 248); and (viii.) detecting the second endpoint using the second set of images.

In certain embodiments, the multilayered material is positioned on a stage (e.g., 125) normal to the focused ion beam (e.g., 118) for the delayering step and wherein the stage (e.g., 125) is tilted positioning the multilayered material normal to the SEM column (e.g., 141) to collect the first set of images. In certain embodiments, the stage (e.g., 125) is positioned normal to the focused ion beam (e.g., 118) for the delayering step and the stage (e.g., 125) is tilted positioning the multilayered material normal to the charged particle microscope column (e.g., 141) to collect the first set of images.

In certain embodiments, the multilayered material is positioned on a stage (e.g., 125) normal to the focused ion beam (e.g., 118) for the delayering step and wherein the stage (e.g., 125) is tilted positioning the multilayered material normal to the SEM column (e.g., 141) to collect the second set of images. In certain embodiments, the stage (e.g., 125) is positioned normal to the focused ion beam (e.g., 118) for the delayering step and the stage (e.g., 125) is tilted positioning the multilayered material normal to the charged particle microscope column (e.g., 141) to collect the first set of images.

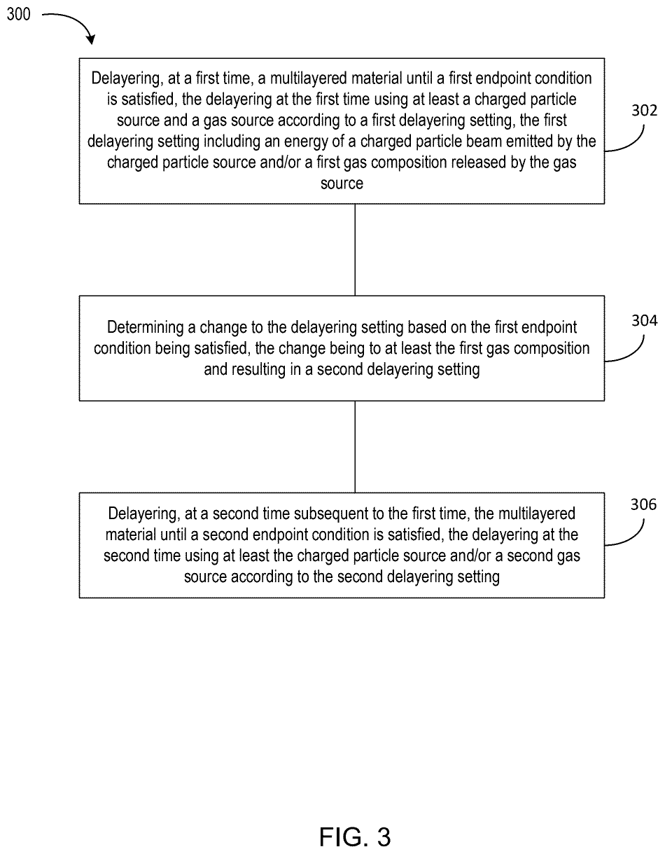

Further to what has been outlined above, FIG. 3 illustrates an example flow for delayering a material 300. In certain embodiments, the flow can be performed by a system, such as the one described in FIG. 1 or 2. In one non-limiting example, the flow includes operation 302, where the system delayers at a first time, a multilayered material until a first endpoint condition is satisfied, the delayering at the first time using at least a charged particle source and a gas source according to a first delayering setting, the first delayering setting controlling an energy of a charged particle beam emitted by the charged particle source and/or a first gas composition released by the gas source. For instance, a controller (e.g., the system controller 119 of FIG. 1 or 219 or FIG. 2) controls a gas injection source (e.g., the gas injection source 146 of FIG. 1 or 246 of FIG. 2) to inject a gas composition into an enveloping chamber (e.g., the chamber 126 of FIG. 1 or 226 of FIG. 2) where the material is present. The controller also controls a charged particle source (e.g., charged particle source 112 in FIG. 1 or 212 of FIG. 2) to emit charged particles forming a beam (e.g., charged particle beam 118 in FIG. 1 or 218 of FIG. 2) towards the material. The controller also controls a SEM (e.g., the SEM 152 of FIG. 1 or SEM 252 of FIG. 2) such that one or more images (e.g., output image 248 of FIG. 2) of the material are generated after specific exposure to the charged particle beam. Such images can be further processed by the controller.

At operation 304, the system switches the delayering based on a first endpoint condition being satisfied. For instance, upon the image processing, the controller may determine that the endpoint condition is met. A memory of the system can store data (e.g., output images 248 of FIG. 2) indicating endpoint conditions that are stratified, where such data can be predefined given an expected structure to be found at a particular set of layers of the material. As such, depending on the stage of the delayering, the controller can determine the relevant endpoint condition and the definition of this endpoint condition to be satisfied from the data stored in the memory. The result of the image processing can be compared to this definition to determine if the endpoint condition is satisfied. In certain embodiments, the endpoint condition can be an increase to a brightness of a structure detected in images, and the endpoint condition being satisfied corresponds to the brightness increase reaching a threshold after exposure to a gas composition after a defined amount of time. In this illustration, the controller can detect the structure, the increase to its brightness from one image to the next and can then compare this increase to the threshold. If the threshold is not yet met, the controller loops back to operation 302. Otherwise, the controller can determine that the endpoint condition is met. In this case, the method can proceed to operation 306, such that the controller can cause a change to the delayering setting based on the first endpoint condition being satisfied. In certain embodiments, when the first endpoint condition is satisfied, the changes to at least the first gas composition may result in a second delayering setting, e.g., a second gas composition.

At operation 306, the system delayers at a second time subsequent to the first time, the multilayered material until a second endpoint condition is satisfied, the delayering at the second time using at least the charged particle source and the gas source according to the second delayering setting, the second delayering setting controlling the energy of the charged particle beam emitted by the charged particle source and/or the second gas composition released by the gas source. In certain embodiments, the second delayering setting includes a different energy for the charged particle beam emitted by the charged particle source and/or a different gas composition released by the gas source when compared to the first delayering setting. In a non-limiting example, the memory of the system can store the different settings to use corresponding to the different delayering stages and the associated endpoint conditions. As such, upon detecting that the first endpoint condition is met, the controller can apply the stored data and define the pre-defined constraints of the second setting to apply. The controller can then cause the charged particle beam and the gas injection source to operate according to the second setting.

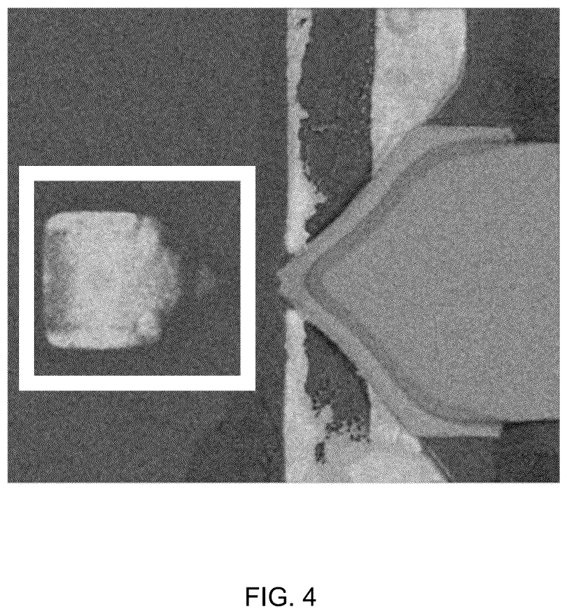

In a non-limiting example, in the first step of the first stage of the delayering process, the paddle grayscale measurement was determined by taking the square root of the sum of square pixels. FIG. 4 shows an SEM image of the first endpoint condition and further shows the focused ion beam (FIB) region in the SEM grayscale measurement of the paddle feature. Herein next, examples of endpoint conditions and image processing procedures to detect whether such conditions are met are described. However, the embodiments of the present disclosure are not limited as such.

In an example, in a stage of the delayering process, the endpoint can be defined as the ratio of the current slice grayscale over the initial slice grayscale as follows:

$$Endpoint Condition = \frac{current slice grayscle}{initial slice grayscale} , \qquad ( Formula I )$$

where a slice grayscale represents a grayscale image generated based on SEM imaging, the current slice grayscale represents the latest SEM image generated and corresponding to the latest charged particle beam and gas composition application, and the initial slice grayscale represents the first SEM image generated after pre-refinement exposure of the material to the charged particle beam and first gas composition for a pre-defined time. Because a ratio is used, the endpoint condition represents an increase to brightness (e.g., a grayscale brightness increase). The endpoint condition is satisfied if this ratio exceeds a threshold, where the threshold can be defined specifically for the delayering stage. In one non-limiting example, the first threshold may be reached when at least a 30% increase in brightness is reached from the first slice measurement according to Formula I.

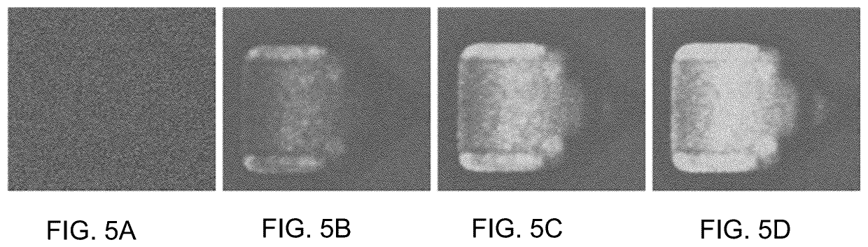

FIGS. 5A-5D are an exemplary visual application of the steps needed to satisfy the first endpoint condition according to Formula I. FIG. 5A-5D show four slices at different stages of delayering to reach a grayscale value increase of 30%. FIG. 5A shows the SEM image of a non-homogenous surface after ion beam and gas exposure of 0 seconds (i.e., slice zero). This represents the stage before starting the delayering process. In certain embodiments, a pre-refinement exposure to the ion beam and the first gas composition follows the collection of the SEM image at slice zero. A pre-refinement exposure time period may be defined by an initial analysis of the material surface to define a set time of exposure before the structure of interest is revealed. Not intending to be bound by theory, a pre-refinement exposure may refer to 98% delayering of the sample material. A pre-refinement exposure may refer to at least 96% delayering, at least 97% delayering, at least 98% delayering, or at least 99% delayering. FIG. 5B shows the SEM image of the sample material after the pre-refinement period was completed. For FIG. 5B, slice one, the pre-refinement exposure time was 1.12358 minutes. Slice one image output defines the first point from which the 30% grayscale increase was calculated according to Formula I for the example of FIGS. 5A-5D. FIG. 5C shows an SEM image taken after a delayering exposure time of 1 second (i.e., slice two). FIG. 5D shows an SEM image after a delayering time of 500 milliseconds (i.e., slice three). In the present example of FIGS. 5A-5D, slice three output image was the point of 30% grayscale increase, defining endpoint one of the delayering flow and as further described below.

The first gas composition used in the example of FIGS. 5A-5D was a mixture of 0.2% AC and 1.7% DE for the first stage of the delayering process until the first endpoint condition was reached and as further outlined in Table 1.

TABLE 1
Exemplary slicing for stage one of the delayering process.

| Recipe Logic: | Delayered Time | | Purpose |
|---|---|---|---|
| If slice number = 0 | 0 | sec | Measure initial paddle GS |
| If slice number = 1 | 98% of previous site total | | Deprocess to near the |
| | delayer time | | end point |
| If current GS condition < 1.01 | 2 | sec | Deprocess with proper |
| If GS condition < 1.1 | 1 | sec | time to reach endpoint |
| If GS condition < 1.25 | 500 | msec | |
| If GS condition < 1.3 | 300 | msec | |

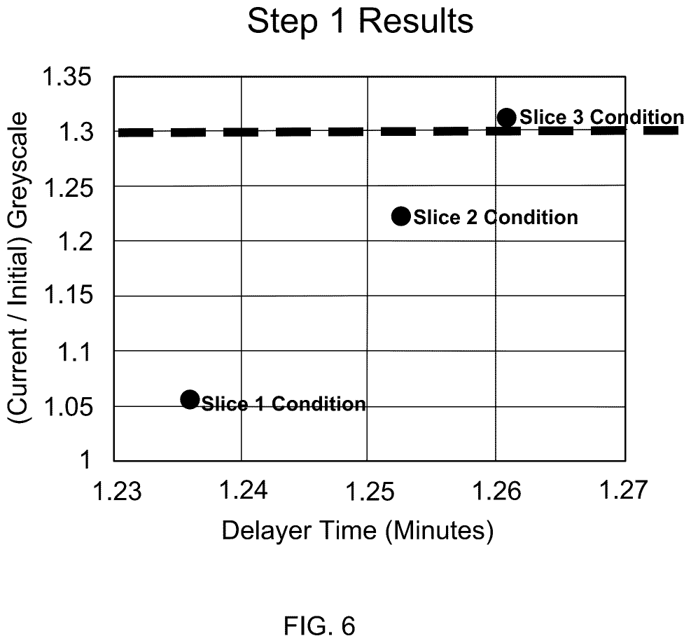

FIG. 6 shows a plot of the current over initial grayscale per delayering time (in minutes), for data in Table 1. As shown in FIG. 6 and as described for FIGS. 5A-5D, the 30% increase was measured using Formula I based on slice one, slice two and slice three. FIG. 6 shows that from slice one to slice three output images there was a 30% increase in grayscale which was determined to be the desired condition for satisfying the first endpoint condition. In another example, more slice outputs may be needed to reach the 30% grayscale increase compared to initial grayscale value therefore, more instances of SEM image collection may be need to satisfy the first endpoint condition for different, for example, heterogeneous materials. As can be appreciated from FIG. 5D the paddle was nearly fully exposed at the end of stage one.

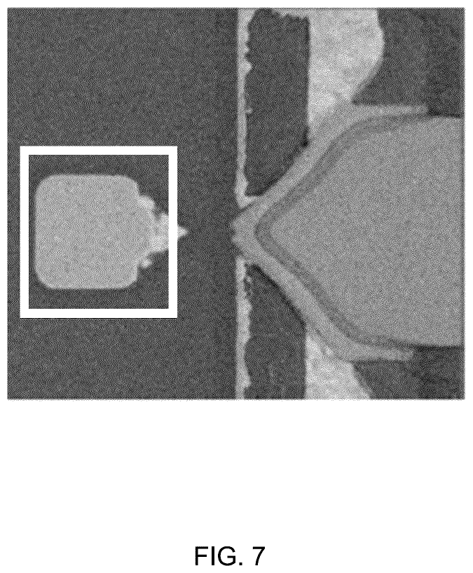

In certain embodiments, the definition of the endpoint condition can vary between stages. Above, a ratio according to Formula I is used and corresponds to a grayscale brightness increase as an example defining the first endpoint condition for a first delayering stage. In a second, subsequent delayering stage, detected geometries of a structure can be used as one or more endpoint conditions for further delayering of the fine features of a given structure. One example of detected geometries can be slopes corresponding to detected boundaries of the structure. In FIG. 7, the structure is shown to have a paddle-like shape. FIG. 7 further shows the FIB pattern rectangle region just after the stage one endpoint, wherein the triangular feature of the paddle is not yet well defined. Delayering of the triangular feature of the paddle was the focus of the second delayering stage. Not intending to be bound by theory, a person of ordinary skill in the art may appreciate the challenges of distinguishing between the triangular tip of the paddle structure and the body of the paddle structure solely by applying grayscale analysis as done for determining the first endpoint condition. Thus, the second endpoint condition may be defined by measuring a slope of the paddle (referred to as a paddle slope). The slope of the paddle may be used to determine if the second endpoint condition is satisfied in two different ways. First, the collection of paddle slope measurements may be used to fit a line wherein once a threshold slope of the best fitted line is reached the second endpoint condition is satisfied. Alternatively, the second endpoint condition may be satisfied once the coefficient of determination (R²; e.g., line fitting the slope detected from multiple SEM images or slices) is within a specific threshold measurement.

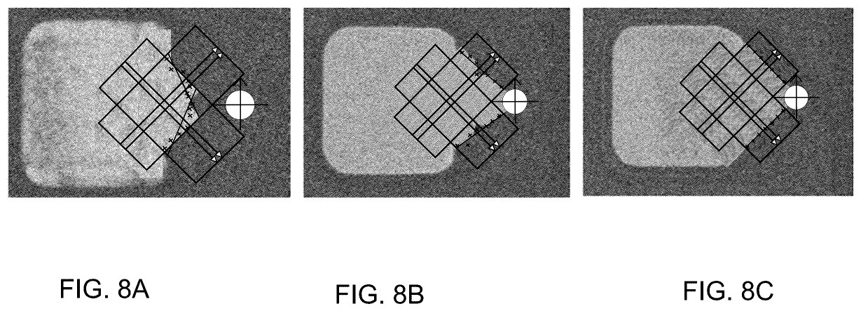

The sample data set in FIGS. 8A-8C show each SEM image (i.e., slice) taken in resolving the triangular feature of the paddle and is a visual representation of reaching the second endpoint. In this non-limiting example, the initial measurements were followed by a delayering of the paddle region using 80% DE gas. The delayering was repeated using 80% DE until the average paddle slope was greater than at least 0.960 or until the average paddle line fit R² was greater than or equal to 0.997. FIG. 8A shows the SEM image of slice zero, taken right after the end of stage one and before the start of stage two, at a time of 0 seconds. As can be observed, the tip of the paddle structure is poorly defined. FIG. 8B shows the SEM image of slice one, taken after three seconds of exposure to 80% DE gas. After three seconds of exposure, the edges of the tip were initially resolved. FIG. 8C shows the SEM image of slice two, taken after six seconds of exposure to 80% DE gas. FIG. 8C shows a fully resolved tip and marks the end of stage two.

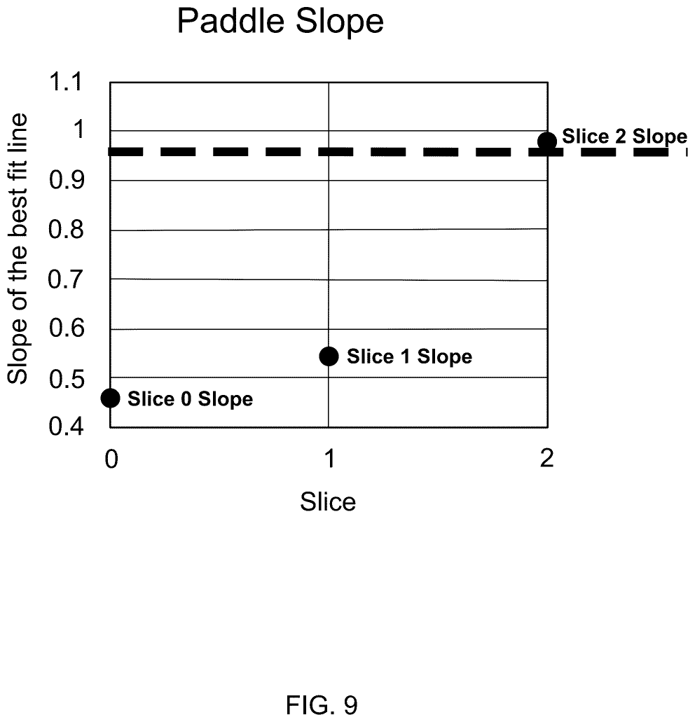

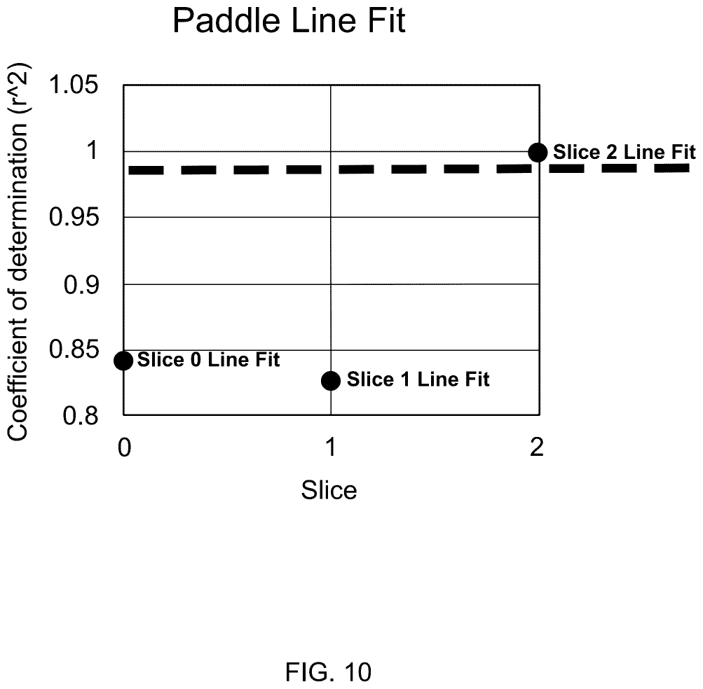

To fully automate reaching stage two, the images collected in FIGS. 8A-8C were coupled with slope measuring software and the two slope measurement analyses described above. At each imaging stage, the measurement of the paddle slope at each of the slice stages taken and as described for FIGS. 8A-8C were recorded. FIG. 9 shows a plot of each paddle slope measurement and the slope of the best fit line versus each paddle slope measurement at each slice stage. The threshold slope of the best fit line was determined to be greater than 0.960. FIG. 9 shows the threshold slope by the dashed line. FIG. 10 shows a plot of the coefficient of determination (R²) versus slice taken. The delayering steps may be carried out until the coefficient of determination (R²) reaches at least 0.997. FIG. 10 shows the threshold coefficient of determination by a dashed line. In the non-limiting example, the paddle was completely delayered at the end of stage two. It is worth noting that some materials may require additional delayering stages to fully resolve the target structure.

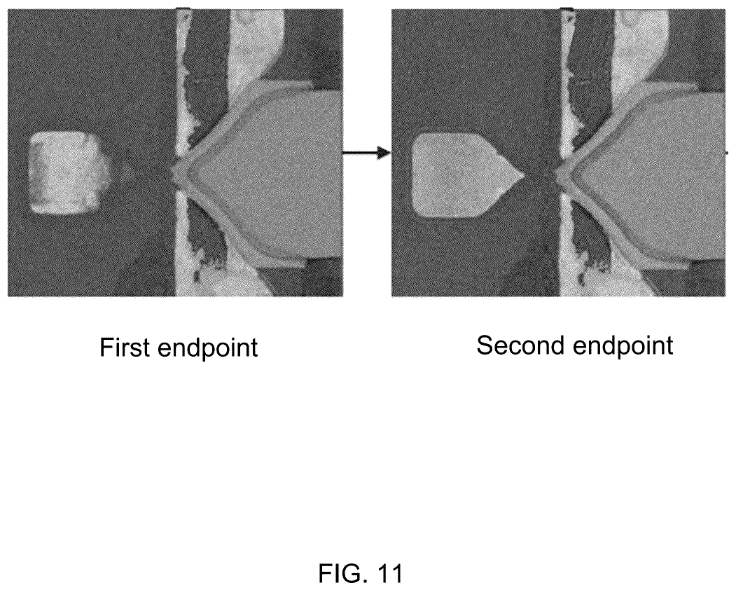

FIG. 11 shows SEM images of the paddle structure at the first endpoint and at the second endpoint. As can be observed, the measurement techniques herein described were successfully applied to automate the resolution of a structure at the first endpoint and refine the resolution of the structure at the second endpoint.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter not be limited to the particular examples disclosed, but that such claimed subject matter may also include all aspects falling within the scope of appended claims, and equivalents thereof.

In certain embodiments, the disclosure relates to a non-transitory computer-readable medium embodying program code comprising instructions which, when executed by a processor, cause the processor to perform operations comprising delayering, at a first time, a multilayered material until a first endpoint condition is satisfied. In certain embodiments, the delayering at the first time uses at least a charged particle source and a gas source according to a first delayering setting. In certain embodiments, the first delayering setting consists of an energy of a charged particle beam emitted by the charged particle source or a gas composition released by the gas source. In certain embodiments, the non-transitory computer readable medium further comprises determining a change to the delayering setting based on the first endpoint condition being satisfied, the change being to at least the gas composition and resulting in a second delayering setting. In certain embodiments, the non-transitory computer-readable medium further comprises delayering, at a second time subsequent to the first time, the multilayered material until a second endpoint condition is satisfied. In certain embodiments, the delayering at the second time uses at least the charged particle source and the gas source according to the second delayering setting. In certain embodiments, the second delayering setting consists of the energy of the charged particle beam emitted by the charged particle source and/or the second gas composition released by the gas source.

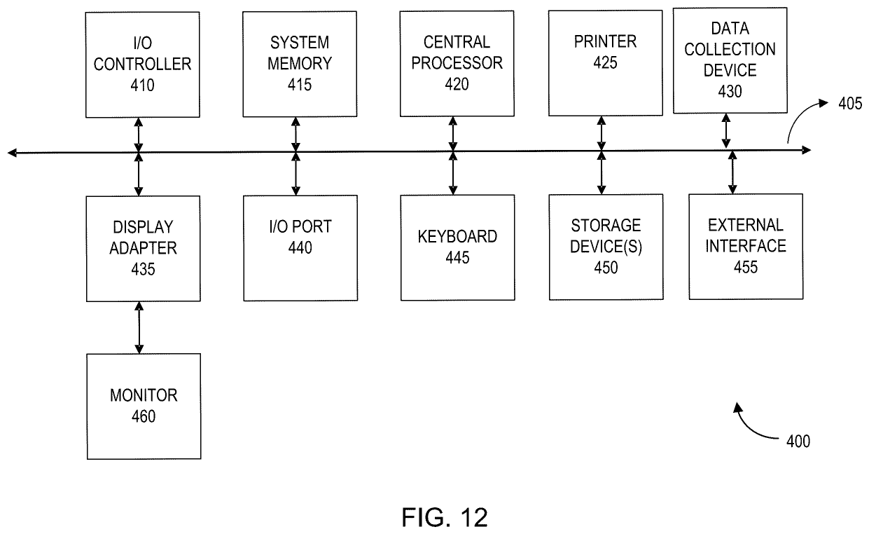

In certain embodiments, the computer-readable medium makes use of a computer system. Component of the computer system or the entirety of the computer system can be included in, integrated with, or interface with one or more components of the system 400. Any of the computer systems with applicable use in practicing the present disclosure may utilize any suitable number of subsystems. An example of such subsystems is shown in FIG. 12 in computer system 400. In some embodiments, a computer system includes a single computer apparatus, where the subsystems can be the components of the computer apparatus. In other embodiments, a computer system can include multiple computer apparatuses, each being a subsystem, with internal components. A computer system can include desktop and laptop computers, tablets, mobile phones and other mobile devices.

The subsystems shown in FIG. 12 are interconnected via a system bus 405. Additional subsystems such as a printer 425, keyboard 445, storage device(s) 450, monitor 460 (e.g., a display screen, such as an LED), which is coupled to display adapter 435, and others are shown. Peripherals and input/output (I/O) devices, which couple to I/O controller 410, can be connected to the computer system by any number of means known in the art such as input/output (I/O) port 440 (e.g., USB, FireWire®). For example, I/O port 440 or external interface 455 (e.g., Ethernet, Wi-Fi, etc.) can be used to connect computer system 400 to a wide area network such as the Internet, a mouse input device, or a scanner. The interconnection via system bus 405 allows the central processor 420 to communicate with each subsystem and to control the execution of a plurality of instructions from system memory 415 or the storage device(s) 450 (e.g., a fixed disk, such as a hard drive, or optical disk), as well as the exchange of information between subsystems. The system memory 415 and/or the storage device(s) 450 may embody a computer readable medium. Another subsystem is a data collection device 430, such as a camera, microphone, accelerometer, and the like. Any of the data mentioned herein can be output from one component to another component and can be output to the user.

A computer system can include a plurality of the same components or subsystems, e.g., connected together by external interface 455, by an internal interface, or via removable storage devices that can be connected and removed from one component to another component. In some embodiments, computer systems, subsystem, or apparatuses can communicate over a network. In such instances, one computer can be considered a client and another computer a server, where each can be part of a same computer system. A client and a server can each include multiple systems, subsystems, or components.

Aspects of embodiments can be implemented in the form of control logic using hardware circuitry (e.g., an application specific integrated circuit or field programmable gate array) and/or using computer software stored in a memory with a generally programmable processor in a modular or integrated manner, and thus a processor can include memory storing software instructions that configure hardware circuitry, as well as an FPGA with configuration instructions or an ASIC. As used herein, a processor can include a single-core processor, multi-core processor on a same integrated chip, or multiple processing units on a single circuit board or networked, as well as dedicated hardware. Based on the disclosure and teachings provided herein, a person of ordinary skill in the art will know and appreciate other ways and/or methods to implement embodiments of the present disclosure using hardware and a combination of hardware and software.

Any of the software components or functions described in this application may be implemented as software code to be executed by a processor using any suitable computer language such as, for example, Java, C, C++, C#, Objective-C, Swift, or scripting language such as Perl or Python using, for example, conventional or object-oriented techniques. The software code may be stored as a series of instructions or commands on a computer readable medium for storage and/or transmission. A suitable non-transitory computer readable medium can include random access memory (RAM), a read only memory (ROM), a magnetic medium such as a hard-drive or a floppy disk, or an optical medium such as a compact disk (CD) or DVD (digital versatile disk) or Blu-ray disk, flash memory, and the like. The computer readable medium may be any combination of such devices. In addition, the order of operations may be re-arranged. A process can be terminated when its operations are completed but could have additional steps not included in a figure. A process may correspond to a method, a function, a procedure, a subroutine, a subprogram, etc. When a process corresponds to a function, its termination may correspond to a return of the function to the calling function or the main function.

Such programs may also be encoded and transmitted using carrier signals adapted for transmission via wired, optical, and/or wireless networks conforming to a variety of protocols, including the Internet. As such, a computer readable medium may be created using a data signal encoded with such programs. Computer readable media encoded with the program code may be packaged with a compatible device or provided separately from other devices (e.g., via Internet download). Any such computer readable medium may reside on or within a single computer product (e.g., a hard drive, a CD, or an entire computer system), and may be present on or within different computer products within a system or network. A computer system may include a monitor, printer, or other suitable display for providing any of the results mentioned herein to a user.

Any of the methods described herein may be totally or partially performed with a computer system including one or more processors, which can be configured to perform the steps. Any operations performed with a processor (e.g., aligning, determining, comparing, computing, calculating) may be performed in real-time. The term “real-time” may refer to computing operations or processes that are completed within a certain time constraint. The time constraint may be 1 millisecond, 1 second, 1 minute, 1 hour, 1 day, or 7 days. Thus, embodiments can be directed to computer systems configured to perform the steps of any of the methods described herein, potentially with different components performing a respective step or a respective group of steps. Although presented as numbered steps, steps of methods herein can be performed at a same time or at different times or in a different order. Additionally, portions of these steps may be used with portions of other steps from other methods. Also, all or portions of a step may be optional. Additionally, any of the steps of any of the methods can be performed with modules, units, circuits, or other means of a system for performing these steps.

In the foregoing specification, embodiments of the disclosure have been described with reference to numerous specific details that can vary from implementation to implementation. The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set of claims that issue from this application, in the specific form in which such claims issue, including any subsequent correction. The specific details of particular embodiments can be combined in any suitable manner without departing from the spirit and scope of embodiments of the disclosure.

Additionally, spatially relative terms, such as “bottom” or “top” and the like can be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a “bottom” surface can then be oriented “above” other elements or features. The device can be otherwise oriented (e.g., rotated 90 degrees or at other orientations) and the spatially relative descriptors used herein interpreted accordingly.

Terms “and,” “or,” and “an/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In certain embodiments, operations or processing may involve physical manipulation of physical quantities. Typically, although not necessarily, such quantities may take the form of electrical or magnetic signals capable of being stored, transferred, combined, compared, or otherwise manipulated. It has proven convenient at times, principally for reasons of common usage, to refer to such signals as bits, data, values, elements, symbols, characters, terms, numbers, numerals, or the like. It should be understood, however, that all of these or similar terms are to be associated with appropriate physical quantities and are merely convenient labels. Unless specifically stated otherwise, as apparent from the discussion herein, it is appreciated that throughout this specification discussions utilizing terms such as “processing,” “computing,” “calculating,” “determining,” or the like refer to actions or processes of a specific apparatus, such as a special purpose computer, special purpose computing apparatus or a similar special purpose electronic computing device. In the context of this specification, therefore, a special purpose computer or a similar special purpose electronic computing device is capable of manipulating or transforming signals, typically represented as physical electronic or magnetic quantities within memories, registers, or other information storage devices, transmission devices, or display devices of the special purpose computer or similar special purpose electronic computing device.

Aspects of the disclosure and the invention may be further understood by reference to the following non-limiting clauses.

Exemplary clauses provided in accordance with the presently disclosed subject matter include, but are not limited to, the claims and the following embodiments:

Clause 1: A method for delayering a heterogeneous material, the method comprising processing the heterogeneous material at a first time by at least:
i. directing a charged particle beam toward the heterogeneous material;
ii. directing a first gas composition toward the heterogenous material;
iii. generating a first set of images of the heterogeneous material; and
iv. detecting a first endpoint using the first set of images;
   processing the heterogeneous material at a second time based on the first endpoint being detected, wherein the processing at the second time comprises:
v. directing the charged particle beam toward the heterogeneous material;
vi. directing a second gas composition toward the heterogenous material;
vii. generating a second set of images of the heterogeneous material; and
viii. detecting a second endpoint using the second set of images.

Clause 2: The method of clause 1, wherein the charged particle beam is a focused ion beam and wherein the energy of the focused ion beam is the same or different for delayering steps i. and v.

Clause 3: The method of clause 1 or clause 2, wherein the first gas composition includes a mixture of at least two gases.

Clause 4: The method of any one of clauses 1 to 3, wherein the first gas composition and the second gas composition differ in the number of gases and/or in the constituent gases that make up each respective composition.

Clause 5: The method of any one of clauses 1 to 4, wherein the first gas composition comprises a mixture of ammonium carbide (AC) and delineated etch (DE) gas.

Clause 6: The method of any one of clauses 1 to 5, wherein the first gas composition comprises between about 0.0% and about 1.0% AC and between about 0.0% and about 80.0% DE.

Clause 7: The method of any one of clauses 1 to 6, wherein the first set of images are scanning electron microscope (SEM) images, and wherein detecting the first endpoint comprises analyzing the SEM images with a grayscale algorithm.

Clause 8: The method of any one of clauses 1 to 7, wherein detecting the first endpoint comprises determining an increase to a grayscale value output by the grayscale algorithm and determining that the increase is within a range, wherein the range is between 15% and 45%.

Clause 9: The method of any one of clauses 1 to 8, wherein the time it takes to arrive at the first endpoint is recorded to automate processing of the heterogeneous material at a first time.

Clause 10: The method of any one of clauses 1 to 9, wherein the second gas composition comprises at least one gas.

Clause 11: The method of any one of clauses 1 to 10, wherein the second gas composition includes DE and excludes AC.

Clause 12: The method of any one of clauses 1 to 11, wherein the second set of images are scanning electron microscope (SEM) images, and wherein detecting the second endpoint comprises processing the SEM images using an edge finding algorithm.

Clause 13: The method of any one of clauses 1 to 12, wherein the detecting the second endpoint comprises measuring a slope for each of the second set of images such that slope measurements are generated; and line fitting the slope measurements until an average of line fitted slope measurements is greater than 0.950 or wherein a coefficient of determination (R²) is greater than 0.996.

Clause 14: A method comprising delayering, at a first time, a multilayered material until a first endpoint condition is satisfied, the delayering at the first time using at least a charged particle source and a gas source according to a first delayering setting, the first delayering setting controlling an energy of a charged particle beam emitted by the charged particle source and/or a first gas composition released by the gas source; determining a change to the delayering setting based on the first endpoint condition being satisfied, the change being to at least the gas composition and resulting in a second delayering setting; and delayering, at a second time subsequent to the first time, the multilayered material until a second endpoint condition is satisfied, the delayering at the second time using at least the charged particle source and the gas source according to the second delayering setting, the second delayering setting controlling the energy of the charged particle beam emitted by the charged particle source and/or the second gas composition released by the gas source

Clause 15: The method of clause 14, wherein the multilayered material is a homogeneous multilayered material or a heterogeneous multilayered material.

Clause 16: The method of clause 14 or clause 15, wherein delayering, at a first time, comprises: (i.) directing a focused ion beam toward the multilayered material; (ii.) directing the first gas composition toward the multilayered material; (iii.) generating a first set of images of the multilayered material; and (iv.) detecting the first endpoint using the first set of images.

Clause 17: The method of any one of clauses 14 to 16, wherein delayering, at a second time subsequent to the first time, comprises: (v.) directing a focused ion beam toward the multilayered material; (vi.) directing the second gas composition toward the multilayered material; (vii.) generating a second set of images of the multilayered material; and (viii.) detecting the second endpoint using the second set of images.

Clause 18: The method of any one of clauses 14 to 17, wherein the multilayered material is positioned on a stage normal to the focused ion beam for the delayering step and wherein the stage is tilted positioning the multilayered material normal to the SEM column to collect the first set of images.

Clause 19: The method of any one of clauses 14 to 18, wherein the multilayered material is positioned on a stage normal to the focused ion beam for the delayering step and wherein the stage is tilted positioning the multilayered material normal to the SEM column to collect the second set of images.

Clause 20: A non-transitory computer-readable medium embodying program code comprising instructions which, when executed by a processor, cause the processor to perform operations comprising delayering, at a first time, a multilayered material until a first endpoint condition is satisfied, the delayering at the first time using at least a charged particle source and a gas source according to a first delayering setting, the first delayering setting controlling an energy of a charged particle beam emitted by the charged particle source or a gas composition released by the gas source; determining a change to the delayering setting based on the first endpoint condition being satisfied, the change being to at least the gas composition and resulting in a second delayering setting; and delayering, at a second time subsequent to the first time, the multilayered material until a second endpoint condition is satisfied, the delayering at the second time using at least the charged particle source and the gas source according to the second delayering setting, the second delayering setting controlling the energy of the charged particle beam emitted by the charged particle source and/or the second gas composition released by the gas source

### REFERENCES

Challener, W., Peng, C., Itagi, A. et al. Heat-assisted magnetic recording by a near-field transducer with efficient optical energy transfer. Nature Photon 3, 220-224 (2009).

### STATEMENTS REGARDING INCORPORATION BY REFERENCE AND VARIATIONS

All references throughout this application, for example patent documents, including issued or granted patents or equivalents and patent application publications, and non-patent literature documents or other source material are hereby incorporated by reference herein in their entireties, as though individually incorporated by reference.

All patents and publications mentioned in the specification are indicative of the levels of skill of those skilled in the art to which the invention pertains. References cited herein are incorporated by reference herein in their entirety to indicate the state of the art, in some cases as of their filing date, and it is intended that this information can be employed herein, if needed, to exclude (for example, to disclaim) specific embodiments that are in the prior art.

When a group of substituents is disclosed herein, it is understood that all individual members of those groups and all subgroups and classes that can be formed using the substituents are disclosed separately. When a Markush group or other grouping is used herein, all individual members of the group and all combinations and sub-combinations possible of the group are intended to be individually included in the disclosure. As used herein, “and/or” means that one, all, or any combination of items in a list separated by “and/or” are included in the list; for example, “1, 2 and/or 3” is equivalent to “1, 2, 3, 1 and 2, 1 and 3, 2 and 3, or 1, 2 and 3”.

Every formulation or combination of components described or exemplified can be used to practice the invention, unless otherwise stated. Specific names of materials are intended to be exemplary, as it is known that one of ordinary skill in the art can name the same material differently. It will be appreciated that methods, device elements, starting materials, and synthetic methods other than those specifically exemplified can be employed in the practice of the invention without resort to undue experimentation. All art-known functional equivalents, of any such methods, device elements, starting materials, and synthetic methods are intended to be included in this invention. Whenever a range is given in the specification, for example, a temperature range, a time range, or a composition range, all intermediate ranges and subranges, as well as all individual values included in the ranges given are intended to be included in the disclosure.

The terms and expressions which have been employed are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by examples, embodiments, and optional features, modification and variation of the concepts herein disclosed may be resorted to by those skilled in the art, and that such modifications and variations are considered to be within the scope of this invention as defined by the appended claims.

What is claimed is:

1. A method for delayering a heterogeneous material, the method comprising:
processing the heterogeneous material at a first time by at least:
i. directing a charged particle beam toward the heterogeneous material;
ii. directing a first gas composition toward the heterogenous material;
iii. generating a first set of images of the heterogeneous material; and
iv. detecting a first endpoint using the first set of images;
processing the heterogeneous material at a second time based on the first endpoint being detected, wherein the processing at the second time comprises:
v. directing the charged particle beam toward the heterogeneous material;
vi. directing a second gas composition toward the heterogenous material;
vii. generating a second set of images of the heterogeneous material; and
viii. detecting a second endpoint using the second set of images.

2. The method of claim 1, wherein the charged particle beam is a focused ion beam and wherein the energy of the focused ion beam is the same or different for delayering steps i. and v.

3. The method of claim 1, wherein the first gas composition includes a mixture of at least two gases.

4. The method of claim 1, wherein the first gas composition and the second gas composition differ in the number of gases and/or in the constituent gases that make up each respective composition.

5. The method of claim 4, wherein the first gas composition comprises a mixture of ammonium carbide (AC) and delineated etch (DE) gas.

6. The method of claim 5, wherein the first gas composition comprises between about 0.0% and about 1.0% AC and between about 0.0% and about 80.0% DE.

7. The method of claim 1, wherein the first set of images are scanning electron microscope (SEM) images, and wherein detecting the first endpoint comprises analyzing the SEM images with a grayscale algorithm.

8. The method of claim 7, wherein detecting the first endpoint comprises determining an increase to a grayscale value output by the grayscale algorithm and determining that the increase is within a range, wherein the range is between 15% and 45%.

9. The method of claim 1, wherein the time it takes to arrive at the first endpoint is recorded to automate processing of the heterogeneous material at a first time.

10. The method of claim 1, wherein the second gas composition comprises at least one gas.

11. The method of claim 10, wherein the second gas composition includes DE and excludes AC.

12. The method of claim 1, wherein the second set of images are scanning electron microscope (SEM) images, and wherein detecting the second endpoint comprises processing the SEM images using an edge finding algorithm.

13. The method of claim 12, wherein the detecting the second endpoint comprises:
measuring a slope for each of the second set of images such that slope measurements are generated; and
line fitting the slope measurements until an average of line fitted slope measurements is greater than 0.950 or wherein a coefficient of determination (R²) is greater than 0.996.

14. A method comprising:
delayering, at a first time, a multilayered material until a first endpoint condition is satisfied, the delayering at the first time using at least a charged particle source and a gas source according to a first delayering setting, the first delayering setting controlling an energy of a charged particle beam emitted by the charged particle source and/or a first gas composition released by the gas source;
determining a change to the delayering setting based on the first endpoint condition being satisfied, the change being to at least the first gas composition and resulting in a second delayering setting; and
delayering, at a second time subsequent to the first time, the multilayered material until a second endpoint condition is satisfied, the delayering at the second time using at least the charged particle source and/or a second gas source according to the second delayering setting.

15. The method of claim 14, wherein the multilayered material is a homogeneous multilayered material or a heterogeneous multilayered material.

16. The method of claim 14, wherein delayering, at a first time, comprises:
i. directing a focused ion beam toward the multilayered material;
ii. directing the first gas composition toward the multilayered material;
iii. generating a first set of images of the multilayered material; and
iv. detecting the first endpoint using the first set of images.

17. The method of claim 14, wherein delayering, at a second time subsequent to the first time, comprises:
v. directing a focused ion beam toward the multilayered material;
vi. directing the second gas composition toward the multilayered material;
vii. generating a second set of images of the multilayered material; and
viii. detecting the second endpoint using the second set of images.

18. The method of claim 16, wherein the multilayered material is positioned on a stage normal to the focused ion beam for the delayering step and wherein the stage is tilted positioning the multilayered material normal to the SEM column to collect the first set of images.

19. The method of claim 17, wherein the multilayered material is positioned on a stage normal to the focused ion beam for the delayering step and wherein the stage is tilted positioning the multilayered material normal to the SEM column to collect the second set of images.

20. A non-transitory computer-readable medium embodying program code comprising instructions which, when executed by a processor, cause the processor to perform operations comprising:
delayering, at a first time, a multilayered material until a first endpoint condition is satisfied, the delayering at the first time using at least a charged particle source and a gas source according to a first delayering setting, the first delayering setting controlling an energy of a charged particle beam emitted by the charged particle source or a gas composition released by the gas source;
determining a change to the delayering setting based on the first endpoint condition being satisfied, the change being to at least the gas composition and resulting in a second delayering setting; and
delayering, at a second time subsequent to the first time, the multilayered material until a second endpoint condition is satisfied, the delayering at the second time using at least the charged particle source and the gas source according to the second delayering setting.
